(19) United States
(12) Patent Application Publication
(10) Pub. No.: US 2023/0275173 A1
(43) Pub. Date: Aug. 31, 2023

(54) STRUCTURES AND METHODS FOR PRODUCING AN OPTOELECTRONIC DEVICE

(71) Applicant: Antora Energy, Inc., Sunnyvale, CA (US)

(72) Inventors: Andrew Joseph PONEC, Fremont, CA (US); Leah Yvonne KURITZKY, Berkeley, CA (US); Emmett Edward PERL, Santa Clara, CA (US); Brendan Melville KAYES, Los Gatos, CA (US)

(73) Assignee: Antora Energy, Inc., Sunnyvale (CA)

(21) Appl. No.: 18/027,329

(22) PCT Filed: Sep. 22, 2021
(86) PCT No.: PCT/US2021/051487

§ 371 Date: Mar. 20, 2023

Related U.S. Application Data
(60) Provisional application No. 63/082,376, filed on Sep. 23, 2020.

(51) Int. Cl. H01L 31/052; H01L 21/78; H01L 21/02; H01L 31/054

(52) U.S. Cl. CPC H01L 31/052; H01L 21/7813; H01L 21/02293; H01L 21/02277; H01L 31/054; H01L 2031/0344

(57) ABSTRACT

The technology relates to producing an optoelectronic device. A method for forming an optoelectronic device on a substrate may include growing an epitaxial structure on the substrate, wherein the substrate comprises a semiconductor material having a lattice constant between 5.7 and 6.0 Angstroms, and wherein the epitaxial structure includes an epitaxial device layer, then depositing a metal layer on the epitaxial structure, and selectively removing the epitaxial layer, thereby separating the optoelectronic device from the substrate. An optoelectronic device may include an optoelectronic device structure including an epitaxial device layer having a lattice constant between 5.7 and 6.0 Angstroms, a metal layer deposited onto a surface of the optoelectronic device structure, and a carrier structure, wherein the optoelectronic device comprises a thin film, single crystal device.

### CROSS-REFERENCE TO RELATED APPLICATIONS

This application claims the benefit of U.S. Provisional Patent Application No. 63/082,376, filed Sep. 23, 2020, which is hereby incorporated by reference in its entirety.

### BACKGROUND

Optoelectronic devices are used in many applications, such as optical fiber communications, laser technology, optical metrology, photovoltaics, and more. It is common to form optoelectronic devices using Gallium Arsenide (GaAs) substrates. However, demand for forming optoelectronic devices on Indium Phosphide (InP) substrates is increasing.

For example, VCSELs are semiconductor laser diodes that emit a laser beam from a top surface (or bottom surface) of the device, contrary to edge-emitting laser diodes (e.g., in-plane lasers). A VCSEL includes a pair of high-reflectivity mirrors that are formed parallel to the surface of the substrate (e.g., the wafer surface), where an active region typically consisting of one or more quantum wells is arranged between the pair of mirrors. The mirrors are typically realized using distributed Bragg reflector (DBR) stacks that are formed by alternating layers of high and low refractive index materials, where each layer has a thickness targeted at a quarter of the wavelength of the light generated in the active region. The reflector need not be a DBR but could also be another interference-based multilayer structure where the targeted layer thicknesses are not a quarter wavelength of the light.

The use of VCSELs based on InP substrates has increased due in large part to the demands of the telecommunications industry, which utilizes the longer wavelengths (e.g., 1.3 to 2.0 μm) associated with materials grown on, at, or near the InP lattice constant. For shorter wavelength devices (e.g., 650 nm to 1.3 μm), other substrates such as GaAs are more commonly used. VCSELs formed on the GaAs substrate typically use DBR mirrors made of epitaxially-grown alternating aluminum gallium arsenide (AlGaAs) and GaAs layers that are closely lattice matched (e.g., having the same or similar lattice constant to the substrate), have relatively large contrast in refractive index to each other, and have high thermal conductivities. In some cases, alternating GaAs and aluminum arsenide (AlAs) layers are used to form the DBR mirrors, which exhibit similar properties. In addition, GaAs-based VCSELs have other advantages over InP-based VCSELs including: higher gain quantum wells; reduced impact of free carrier absorption (FCA) due to the shorter emission wavelength; and oxidation of AlAs or AlGaAs can be used to provide good current and optical confinement within the device.

While InP-based VCSELs are preferred for the longer operating wavelengths of the laser emission generated by the devices, these VCSELs suffer from a variety of challenges. First, there are not the same good options for lattice-matched, high refractive index contrast materials to construct the interference-based multilayer mirrors. In addition, active region materials such as gallium indium arsenide phosphide (GaInAsP) quantum wells have lower gain compared to GaAs quantum wells; InP p-type layers have higher FCA; and there are fewer strategies for current and optical confinement to the center of the device. Thus, there is a need for addressing these issues and/or other issues associated with the prior art.

### BRIEF SUMMARY

The present disclosure provides structures and methods for producing an optoelectronic device, including fabricating optoelectronic devices (e.g., thin film, single crystal devices) based on substrates with a lattice constant at or near that of InP (e.g., between 5.7 and 6.0 Angstroms) by epitaxial lift-off. A method for forming an optoelectronic device on a substrate may include: growing an epitaxial structure on the substrate, wherein the substrate comprises a semiconductor material having a lattice constant between 5.7 and 6.0 Angstroms, and wherein the epitaxial structure includes an epitaxial device layer; depositing a metal layer on the epitaxial structure; and selectively removing the epitaxial structure and metal layer from the substrate, thereby separating the optoelectronic device from the substrate. In some examples, the epitaxial structure further comprises a release layer with a high aluminum content. In some examples, selectively removing the epitaxial structure and metal layer from the substrate occurs by epitaxial lift off (ELO). In some examples, the epitaxial lift off comprises exposing the epitaxial layer to a hydrofluoric acid (HF) solution. In some examples, the epitaxial device layer is resistant to the HF solution. In some examples, the metal layer is resistant to the HF solution. In some examples, the optoelectronic device comprises a thermophotovoltaic (TPV) device. In some examples, the optoelectronic device comprises a vertical cavity surface emitting laser (VCSEL) device. In some examples, the metal layer comprises a reflective metal. In some examples, the reflective metal is formed from one, or a combination, of gold, silver, aluminum, or copper. In some examples, the metal layer comprises a supportive metal. In some examples, the supportive metal is formed from one, or a combination, of nickel, molybdenum, or copper. In some examples, the metal layer comprises a dielectric material. In some examples, the dielectric material includes one, or a combination, of arsenic trisulfide, arsenic triselenide, tantalum pentoxide, magnesium fluoride, SU-8, PermiNex®. In some examples, the method further includes placing the optoelectronic device with the metal layer on a carrier structure. In some examples, the substrate comprises Indium Phosphide. In some examples, the method further includes post-processing the substrate for reuse. In some examples, growing the epitaxial layer includes using one, or a combination, of metal organic chemical vapor deposition (MOCVD), molecular beam epitaxy (MBE), hydride vapor deposition (HYPE), or liquid phase epitaxy (LPE).

An optoelectronic device may include: optoelectronic device structure including an epitaxial device layer having a lattice constant between 5.7 and 6.0 Angstroms; a metal layer deposited onto a surface of the optoelectronic device structure; and a carrier structure, wherein the optoelectronic device comprises a thin film, single crystal. In some examples, the optoelectronic device structure comprises a thermophotovoltaic (TPV) device. In some examples, the optoelectronic device structure comprises a vertical cavity surface emitting laser (VCSEL) device. In some examples, the metal layer comprises a reflective metal. In some examples, the reflective metal is formed from one, or a combination, of gold, silver, aluminum, or copper. In some examples, the metal layer comprises a supportive metal. In some examples, the supportive metal is formed from one, or a combination, of nickel, molybdenum, or copper. In some examples, the epitaxial device layer is grown on an epitaxial release layer, which in turn is grown on a substrate by one, or a combination, of metal organic chemical vapor deposition (MOCVD), molecular beam epitaxy (MBE), hydride vapor deposition (HYPE), or liquid phase epitaxy (LPE). In some examples, the substrate comprises Indium Phosphide.

In some examples, the carrier structure is a wafer. In some examples, the optoelectronic device may include: an optoelectronic device structure; a metal layer deposited onto a surface of the optoelectronic device structure; and a carrier structure, wherein the optoelectronic device structure is grown on an epitaxial release layer grown on a substrate prior to deposition of the metal layer, the epitaxial release layer configured to be selectively removed by epitaxial lift-off, thereby separating the optoelectronic device structure and the metal layer from the substrate.

A method for forming a vertical-cavity surface-emitting laser (VCSEL) on a substrate may include: growing epitaxial layers on the substrate, wherein the epitaxial layers include epitaxial device layers, and wherein the substrate comprises a semiconductor material having a lattice constant between 5.7 and 6.0 Angstroms; depositing a first mirror on a first side of the epitaxial device layers; separating the epitaxial device layers from the substrate; and depositing a second mirror on a second side of the epitaxial device layers opposite the first side of the epitaxial layers. In some examples, the semiconductor material is indium phosphide (InP). In some examples, the semiconductor material is indium gallium arsenide (InGaAs). In some examples, the epitaxial layers further include a release layer formed between the substrate and the epitaxial device layers, and separating the epitaxial device layers comprises utilizing an acidic solution to dissolve the release layer via epitaxial lift-off (ELO). In some examples, the acidic solution is a hydrofluoric (HF) acid solution. In some examples, the epitaxial layers further include a release layer formed between the substrate and the epitaxial device layers, and separating the epitaxial device layers comprises utilizing an ultraviolet laser to de-laminate the release layer from the substrate or a buffer layer formed on the substrate via laser lift-off (LLO). In some examples, separating the epitaxial device layers comprises destructive dissolution of the substrate. In some examples, the first mirror is a first dielectric mirror. In some examples, the first dielectric mirror comprises alternating layers of arsenic trisulfide (As₂S₃) or arsenic triselenide (As₂Se₃) or tantalum pentoxide (Ta₂O₅) paired with magnesium fluoride (MgF₂) or silica (SiO₂) In some examples, the epitaxial device layers comprise an active region with multiple quantum wells and a buried tunnel junction. In some examples, the method also may include depositing an optomechanical support layer on a top surface of the first mirror prior to separating the epitaxial device layers from the substrate. In some examples, the optomechanical support layer comprises a metal material. In some examples, the optomechanical support layer includes a mirror formed of a material selected from gold, silver, aluminum, or copper. In some examples, the optomechanical support layer is transparent or semi-transparent and the emission direction of the laser is configured to pass through the optomechanical support layer and emerge from a bottom surface of the VCSEL.

A laser diode may include: a first mirror comprising a plurality of interference-based reflector layers; a number of epitaxial device layers including at least an active region having multiple quantum wells; and a second mirror comprising a second plurality of interference-based reflector layers. In some examples, the plurality of dielectric layers comprise alternating layers of arsenic trisulfide (As₂S₃) or arsenic triselenide (As₂Se₃) or tantalum pentoxide (Ta₂O₅) paired with magnesium fluoride (MgF₂) or silica (SiO₂) In some examples, the epitaxial device layers further include a buried tunnel junction. In some examples, the epitaxial device layers include a front contact layer and a back contact layer, and wherein the front contact layer and the back contact layer are both n-type contact layers.

### BRIEF DESCRIPTION OF THE DRAWINGS

FIG. 1A illustrates a semiconductor wafer including a number of VCSELs formed thereon, in accordance with some embodiments.

FIG. 1B illustrates a process flow for producing an optoelectronic device by ELO, in accordance with some embodiments.

FIG. 2 illustrates a flowchart of a method for manufacturing VCSELs on an InP substrate, in accordance with some embodiments.

FIGS. 3A-3G show a cross-section of the VCSEL at different stages in the production, in accordance with some embodiments.

FIG. 4 illustrates a VCSEL, in accordance with a first embodiment.

FIG. 5 illustrates a VCSEL, in accordance with a second embodiment.

FIG. 6 illustrates a VCSEL, in accordance with a third embodiment.

FIG. 7 illustrates a VCSEL, in accordance with a fourth embodiment.

FIG. 8 illustrates a VCSEL, in accordance with a fifth embodiment.

FIG. 9 illustrates a VCSEL, in accordance with a sixth embodiment.

FIG. 10 illustrates a multi-layered, strain-balanced release layer, in accordance with some embodiments.

FIG. 11 illustrates an optoelectronic device, in accordance with a seventh embodiment.

FIG. 12 illustrates a flowchart of a method for manufacturing an optoelectronic device by ELO, in accordance with some embodiments.

The figures depict various example embodiments of the present disclosure for purposes of illustration only. One of ordinary skill in the art will readily recognize form the following discussion that other example embodiments based on alternative structures and methods may be implemented without departing from the principles of this disclosure and which are encompassed within the scope of this disclosure.

### DETAILED DESCRIPTION

The VCSELs and other optoelectronic devices described in more detail herein are formed using a process that includes separation of the first optional mirror and a number of epitaxial layers from the InP substrate prior to formation of the second optional mirror. Separation of the substrate from the epitaxial layers and the first mirror can be performed via epitaxial liftoff (ELO) using a solution such as a hydrofluoric acid (HF) solution, or via laser lift off using a UV (ultraviolet) wavelength laser. In the case of ELO, a sacrificial release layer with high aluminum content is typically grown prior to growing the epitaxial device layers, the release layer being significantly more susceptible to etching by the HF than the epitaxial device layers. The HF solution may be heated, for example to between 50° C. and 90° C. (e.g., 65° C., 70° C., 75° C., or more, less, or between). The HF solution may be diluted in water (H₂O), for example to between 10% and 50% concentration by volume (e.g., 20%, 25%, 30%, or more, less, or between). Other additives, such as surfactants and/or corrosion inhibitors may also be added to the HF solution. Alternatively, a sacrificial layer may be formed of other materials, such as graphene (carbon), or sodium chloride (NaCl), or a porous layer. Alternatively, the separation may be done by mechanical spalling, or by acoustic liftoff or sonic liftoff (also known as sonic wafering). Alternatively, the separation may be performed by complete dissolution of the substrate. For example, an InP wafer can be dissolved, with high selectivity relative to an InGaAs device, using a hydrochloric acid (HCl) solution. The process of separation of the substrate from the epitaxial layers enables the layers of the mirror to be formed from a larger subset of materials than is commonly available using conventional techniques for forming VCSELs on InP substrates.

Other optoelectronic device types can also benefit from the use of InP substrates. For example, thermophotovoltaic (TPV) devices may be optimized to receive light from a source at a lower temperature than the sun (which is the illumination source for related photovoltaic (PV) devices), and as such may benefit from lower bandgap materials than are often used in PV devices. InP substrates provide for the possibility of making high-quality InGaAs TPV devices.

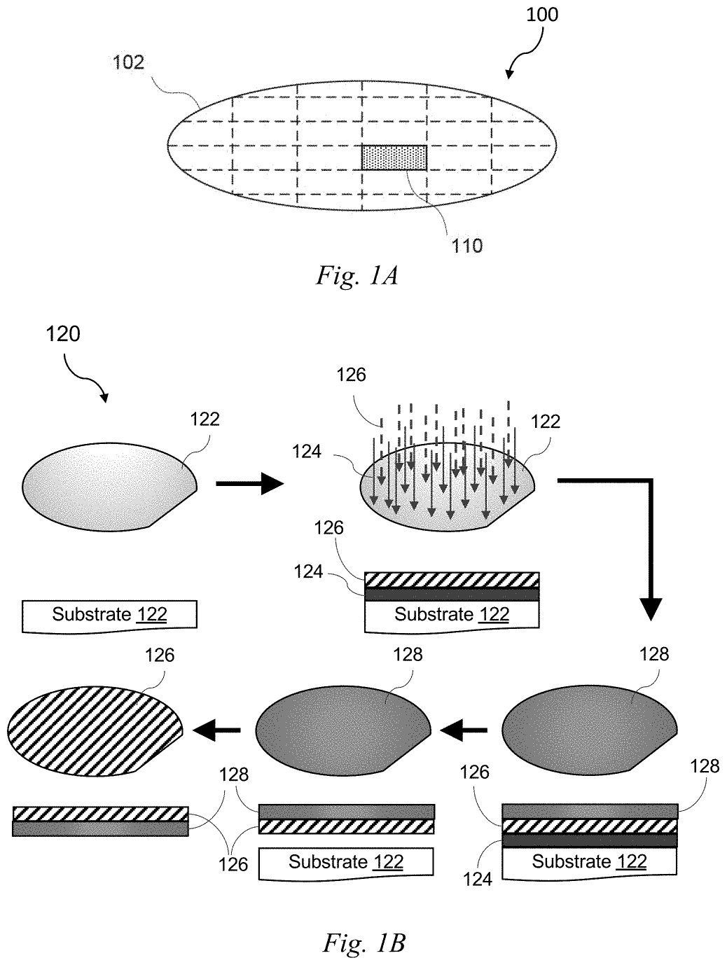

FIG. 1A illustrates a semiconductor wafer 100 including a number of VCSELs formed thereon, in accordance with some embodiments. As depicted in FIG. 1, a substrate 102 is provided for forming a number of VCSELs thereon. The substrate 102 is an InP semiconductor material cut into a wafer (e.g., circular or other shapes) and having a nominal thickness (e.g., between 100 μm and 1 mm, between 600 μm and 625 μm, or other thickness in the μm to mm range). A number of VCSELs are formed on the substrate 102 and then the substrate is singulated (e.g., separated) into a plurality of dies 110, each die 110 usually having a single VCSEL formed thereon. In some embodiments, a die 110 can include an array of VCSELs. It will be appreciated that the number or size of the dies shown in FIG. 1 is not to scale and that the size of each die and the total number of dies that are arranged on a single wafer depends on the size of the substrate and a design of the VCSEL components formed thereon. For example, 10,000-15,000 VCSELs can fit onto a single 3-inch InP wafer.

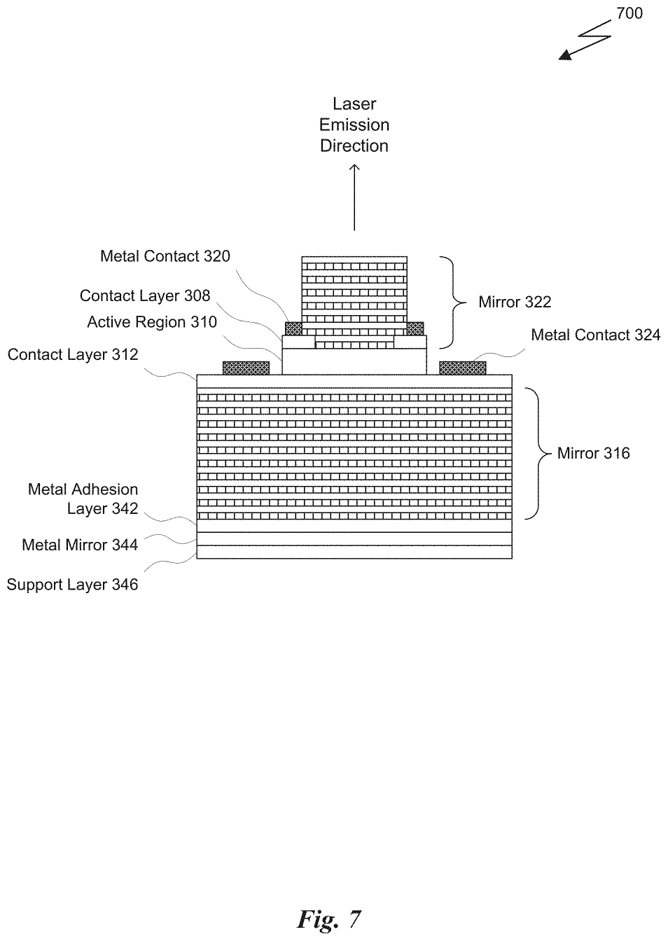

FIG. 1B illustrates a diagram illustrating a process flow for producing an optoelectronic device by ELO, in accordance with some embodiments. In diagram 120, substrate 122 is provided, and then a release layer 124 and an optoelectronic device layer 126 (e.g., photovoltaic (PV), thermophotovoltaic (TPV), light emitting diode (LED), laser, or other device) are grown and/or deposited onto substrate 122 (e.g., by thin film deposition or epitaxy such as metal-organic chemical vapor deposition (MOCVD), hydride vapor phase epitaxy (HYPE), liquid phase epitaxy (LPE), or molecular beam epitaxy (MBE)). Substrate 122 may comprise any of the substrate types described herein, such as a semiconductor material (e.g., InP) having a lattice constant between 5.7 and 6.0 Angstroms. In some examples, the release layer 124 may comprise a single layer or a multi-layer stack of epitaxial layers, as described herein. In some examples, a metal layer 128 of substantial thickness, as described below, may be deposited onto optoelectronic device 126 (e.g., by metal deposition techniques such as electroplating, evaporation, sputtering, etc.), the metal layer 128 forming a flexible film with optoelectronic device 126. Metal layer 128 may comprise a highly reflective metal (e.g., metal mirror 344 in FIG. 7, metal layers 1112 in FIG. 11) or combination of said highly reflective metal with a supportive metal layer (e.g., support layer 346 in FIG. 7, metal layers 1112 in FIG. 11), as described herein. Metal layer 128, whether a single layer or a stack of multiple layers, may act as an optomechanical support for the device. The thickness of 128 may range from a few nanometers to a few millimeters and is typically between 3 micrometers and 50 micrometers (e.g., 5 μm, 8 μm, 25 μm, or more, less, or in between). In some embodiments additional mechanical support is provided by plastic layers that are attached to layer 128, on the opposite surface relative to layer 126. Release layer 124 may be selectively removed (e.g., using ELO techniques, as described herein) to separate the substrate from the flexible film (e.g., optoelectronic device 126 and metal layer 128). Substrate 122 may be saved for later use (e.g., polished for reuse in the same process, or otherwise processed for use in a different process). The flexible film may be inverted (e.g., flipped over) and placed on a carrier structure (e.g., wafer). In other examples, the steps shown in diagram 120 may be performed in a different order, for example, depositing metal layer 128 after removal of release layer 124.

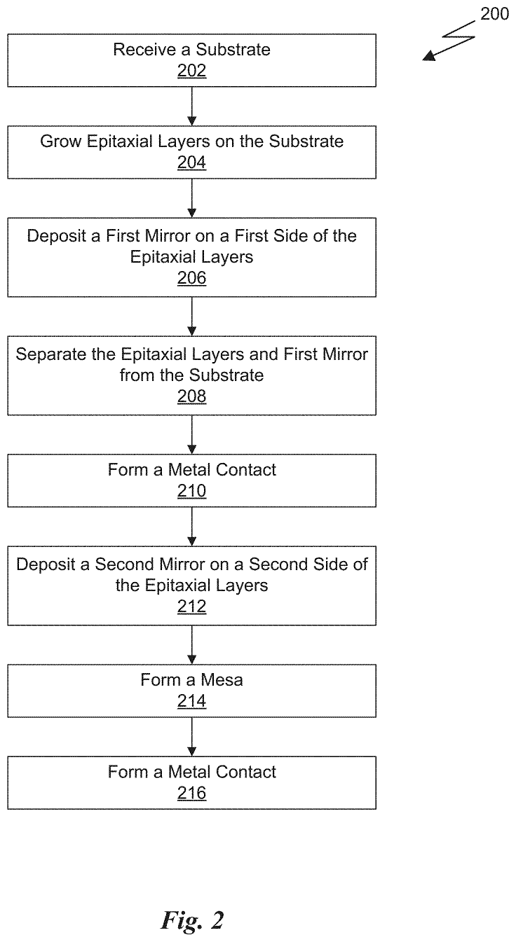

FIG. 2 illustrates a flowchart of a method 200 for manufacturing VCSELs on an InP substrate, in accordance with some embodiments. It will be appreciated that the method 200 is described in the context of semiconductor manufacturing equipment used to perform processing steps including, but not limited to, lithography, surface passivation, ion implantation, etching, vapor deposition, epitaxy, annealing, lift-off, dicing, polishing, and the like. It will be appreciated that any process that results in deposition or removal of the structures described herein is within the scope of the present disclosure.

At step 202, a substrate is received. In an embodiment, the substrate is a circular wafer having a diameter between 2 and 6 inches and a thickness of 350 to 800 μm. It will be appreciated that the dimensions of the substrate are not limited herein and that the substrate can have a rectangular or other shape, a diameter of less than 2 inches or greater than 6 inches, and have a thickness of less than 350 μm or greater than 800 μm. The substrate can be polished on one or both sides. The substrate can be n-type (undoped, unintentionally doped, or doped with Sulfur (S), Tin (Sn), or the like), p-type (doped with Zn or the like), or semi-insulating (doped with Fe or the like). In an embodiment, the substrate is a semiconductor material having a lattice constant between 5.7 and 6.0 Angstroms, such as an indium phosphide (InP) semiconductor material. In other embodiments, the substrate need not be limited to traditional InP wafers but may also include substrates that are manufactured such that only the epitaxy-ready surface has the InP chemistry or lattice constant. Examples of this include thin layers of InP transferred to a foreign substrate (e.g., InP on GaAs (InPoGaAs), InP on Ge (InPoGe), or InP on Si (InPoSi)) and metamorphic grading from one substrate type (e.g., GaAs, Ge, GaSb, or Si) to a lattice constant at or near the lattice constant of InP.

At step 204, epitaxial layers are grown on the substrate. In an embodiment, the epitaxial layers can include, listed in the order of growth on the substrate starting from an adjacent layer, an optional buffer layer, an optional etch stop layer, an optional release layer, a front contact layer, an optional front window and etch stop layer, an active region, an optional back window, and a back contact layer. In an embodiment, the front contact layer and the back contact layer are associated with metal contacts that connect the device to an electrical signal (e.g., a voltage). In some cases, the metal contacts can be referred to as a cathode and an anode. In one embodiment, the front contact layer is associated with the cathode and the back contact layer is associated with the anode. In other embodiments, the front contact layer can be associated with the anode and the back contact layer can be associated with the cathode. In another embodiment, the order of the etch stop layer and the release layer is reversed. The optional etch stop layer and the optional release layer are of suitable materials to allow for the remaining epitaxial layers to be separated from the substrate during a later step; the separated layers can be referred to, collectively, as epitaxial device layers and can include at least the active region, the front contact layer, and the back contact layer. The active region, the front contact layer, and the back contact layer are n-type or p-type layers of semiconductor material (e.g., InGaAs, InP, AlInGaAs, InGaAsP, GaAsSb, GaInAsSb, AlGaAsSb, AlGaInAsSb, and alloys or combinations thereof). The active region may include a plurality of thin (e.g., 5-20 nm) layers of alternating semiconductor materials forming multiple quantum well structures. Single quantum well structures are also possible. The active region often comprises, for example, InGaAs, AlInGaAs, InGaAsP, GaAsSb, AlGaAsSb, AlInGaAs or InGaAsP multiple quantum wells and the epitaxial layers can be formed via molecular beam epitaxy (MBE), metal-organic chemical vapor deposition (MOCVD), hydride vapor phase epitaxy (HYPE), or liquid phase epitaxy (LPE), or other modified variants of these epitaxial growth techniques. In some examples, the epitaxial layers may be grown using a combination or series of techniques, for example, a release layer may be grown by MBE with subsequent layers grown by other techniques. The active regions can also include other heterobarrier or window materials surrounding the quantum wells, the materials including, but not limited, to InP, AlInGaP, InGaP, InGaAsP, AlInGaAs, InGaAs, AlInAs, GaAsSb, AlGaAsSb, AlAsSb, GaPSb, InGaPSb, or AlInGaAs. In other embodiments, the active region can comprise heterostructures, quantum well structures, or quantum dot structures formed from other semiconductor materials using any well-known epitaxy techniques. The materials in the active region may be lattice-matched to the lattice constant of the substrate or may be strained and not lattice-matched to the lattice constant of the substrate. Alternatively, the active region may comprise both lattice-matched and non-lattice-matched materials.

At step 206, a first mirror is deposited on or wafer bonded to a first side or surface of the epitaxial layers. The first mirror can include a plurality of interference-based reflector layers. In an embodiment, the first mirror is deposited on the back contact layer and is located opposite from the substrate such that the epitaxial layers are disposed (i.e., positioned) between the substrate and the first mirror. In an embodiment, the first mirror includes alternating layers of dielectric material, with each layer having a thickness of approximately one quarter of the wavelength of the laser beam generated by the quantum wells in the active region. The first mirror can be referred to as a distributed Bragg reflector (DBR). In an embodiment, the first mirror is a first dielectric mirror that includes alternating layers of arsenic trisulfide (As₂S₃) or arsenic triselenide (As₂Se₃) or tantalum pentoxide (Ta₂O₅) paired with layers of magnesium fluoride (MgF₂) or silica (SiO₂). In other embodiments, additional materials can be substituted in lieu of the combinations of As₂S₃/As₂Se₃/Ta₂O₅ paired with MgF₂/SiO₂, which will be discussed in more detail below. In other embodiments, the mirror is not a DBR; instead, the first mirror is another interference-based multilayer structure with targeted layers having a thickness that might not be equal to a quarter wavelength of the light.

In an embodiment, the first mirror can include one or more pairs of alternating layers, where the number of pairs is typically one to a few, and usually no more than tens of pairs. In some embodiments, an optomechanical support structure is optionally deposited or bonded on top of the first mirror. In an embodiment, the optomechanical support structure comprises a metal layer that has a thickness sufficient to provide structural support to the epitaxial layers and the first mirror. In other embodiments, a metal adhesion layer and a metal mirror can be deposited on top of the first mirror prior to the optomechanical support layer. The options for the metal or metals can include aluminum, nickel, chromium, silver, gold, copper, tungsten, molybdenum, titanium, platinum, palladium, alloys thereof, and the like.

At step 208, the epitaxial layers are separated from the substrate. In an embodiment, a process referred to as ELO can be used to separate the epitaxial layers from the substrate. It will be appreciated that any structures attached to the epitaxial layers, such as the first mirror and the optional optomechanical support structure will also be separated from the substrate as they are attached to an opposite side of the epitaxial device layers from the substrate. In an embodiment, the wafer is submerged in an acidic solution, such as a hydrofluoric (HF) acid solution, which dissolves the release layer. The substrate and buffer layer are released from the remainder of the epitaxial device layers. The epitaxial device layers and any additional layers formed thereon are released from the substrate and inverted such that the optomechanical support structure is located on the bottom of the stack and the front contact layer is located on the top of the stack, ready for the next stage of the manufacturing process. In other embodiments, alternative substrate separation techniques may be utilized, including, but not limited to, laser lift-off, spalling/peeling, acoustic/sonic, or destructive substrate removal to separate the substrate from the epitaxial layers. Alternatively, the release layer may be graphene, or a salt such as sodium chloride, or a porous film, and (if needed) the selective etchant may vary accordingly. In other embodiments, the epitaxial device layers may be transferred and inverted multiple times using temporary support structures (if needed) to accommodate processing objectives in order to produce the final form of the device. The procedure could potentially allow for the separation of the epitaxial layers from the substrate to occur prior to the deposition of the first mirror.

In the case of non-destructive substrate separation techniques, such as ELO, it will be appreciated that the substrate can then be reused to form additional VCSELs as the substrate is not consumed by these processes. In some cases, the substrate may be post-processed by dissolving or otherwise removing the buffer layer from the surface of the substrate. In some embodiments, the substrate is polished before being reused for subsequent production runs.

It will be appreciated that the most common release layer for ELO is AlAs, which is not lattice-matched to InP. In some embodiments, AlAs can still be used as the release layer, given the fact that the small thickness of the release layer (e.g., ˜10 nm) may be at, near, or less than the critical thickness for relaxation. Therefore, there may be little or no disturbance to the crystal lattice structure of the device layers grown on top of the release layer. In other embodiments, the release layer can be formed from AlₓIn₁₋ₓAs with a high aluminum content (e.g., ˜0.47<x≤1, with the lattice constant of AlₓIn₁₋ₓAs matching that of InP when x≈0.48). Using this material can cause a reduction in the ELO etch rate, requiring longer submersion in the acidic solution. In other embodiments, the release layer can be formed from AlAs_{y}Sb_{1-y}, with the lattice constant of AlAs_{y}Sb_{1-y} matching the lattice constant of InP when y≈0.56. In other embodiments, the release layer can be formed from AlₓIn₁₋ₓAlAs_{y}Sb_{1-y} with ˜0.47<x≤1. In yet other embodiments, a strain-balanced approach, described in more detail below, can be used to compensate for strain introduced by using a non-lattice-matched material such as AlAs for the release layer. For example, layers of AlAs and InAlAs, or AlAs and InAs, or AlAs and AlSb can be used as the release layer by forming a strain-balanced superlattice structure.

At step 210, a metal contact is formed on the front (i.e., top) contact layer. The metal contact is used to connect the VCSEL to a terminal of a power source (e.g., a negative terminal). In an embodiment, a metal layer is deposited using common metallization techniques such as plating, evaporation, sputtering, or chemical vapor deposition. The metal layer can be patterned to form the metal contact on the front contact layer using liftoff or etching techniques. The options for metal can include aluminum, nickel, chromium, silver, gold, copper, tungsten, molybdenum, titanium, platinum, palladium, germanium, alloys thereof, and the like.

At step 212, a second mirror is deposited on a second side of the epitaxial layers. The second mirror can also include a plurality of interference-based reflector layers. In an embodiment, the second mirror is a dielectric mirror. In an embodiment, the second mirror is located on an opposite side of the epitaxial layers from the first mirror, such that the active region is disposed between the first mirror and the second mirror. The second mirror can be similar to the first mirror; however, in some embodiments, the second mirror can include a different number of pairs of alternating layers. In addition, in some embodiments, the materials used to form the pairs of alternating layers of the second mirror can be different from the materials used to form the pairs of alternating layers of the first mirror.

At step 214, a mesa is formed by removing a portion of the epitaxial layers. The mesa refers to a structure of the active region below the second mirror that supports the front contact layer, the metal contact, and the second mirror. The remaining portion of the active region is removed via patterned etching or the like, and the back contact layer is exposed.

At step 216, a metal contact is formed on the back contact layer. The metal contact is used to connect the VCSEL to a terminal of a power source (e.g., a positive terminal). In an embodiment, a metal layer is deposited using common metallization techniques such as plating, evaporation, sputtering, or chemical vapor deposition. The metal layer can be patterned to form the metal contact on the back contact layer using liftoff or etching techniques. In some embodiments, where the VCSEL includes a tunnel junction, for example, the back contact layer can be an n-type semiconductor material, as will be discussed in more detail below. Again, the types of metal can include aluminum, nickel, chromium, silver, gold, copper, tungsten, molybdenum, titanium, platinum, palladium, germanium, alloys thereof, and the like.

The method 200 produces a number of VCSELs on a single semiconductor substrate, which, in some embodiment, can be recovered during step 208. The VCSELs formed in the released film can then be separated via dicing and packaged in a laser diode body, which may include one or more optical components such as a lens. Each separated die can include one or more VCSELs, where multiple VCSELs can be packaged as a VCSEL array.

It will also be appreciated that each step described above can include multiple distinct steps or processes. For example, forming a particular layer can include lithography, deposition, etching, polishing, and/or cleaning steps before a subsequent layer is formed or material is removed. Those of skill in the art will understand the processes and/or techniques well-known in the art for forming the layers or structures described above to be within the scope of the disclosure.

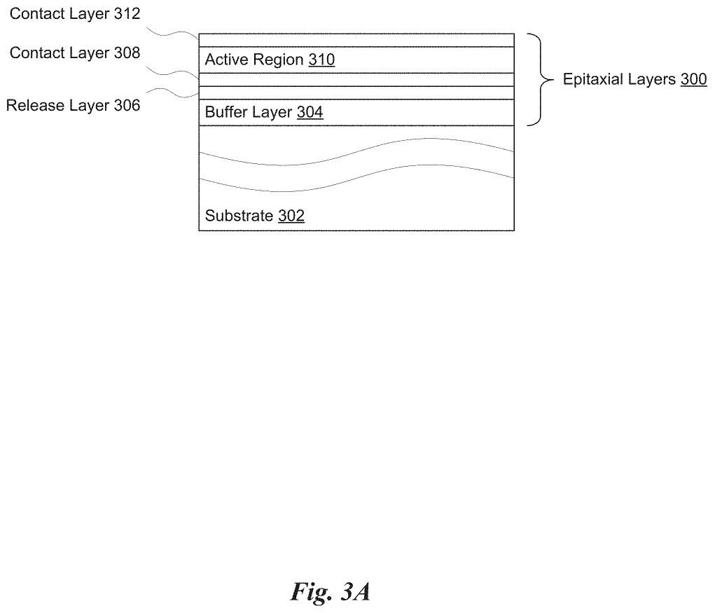

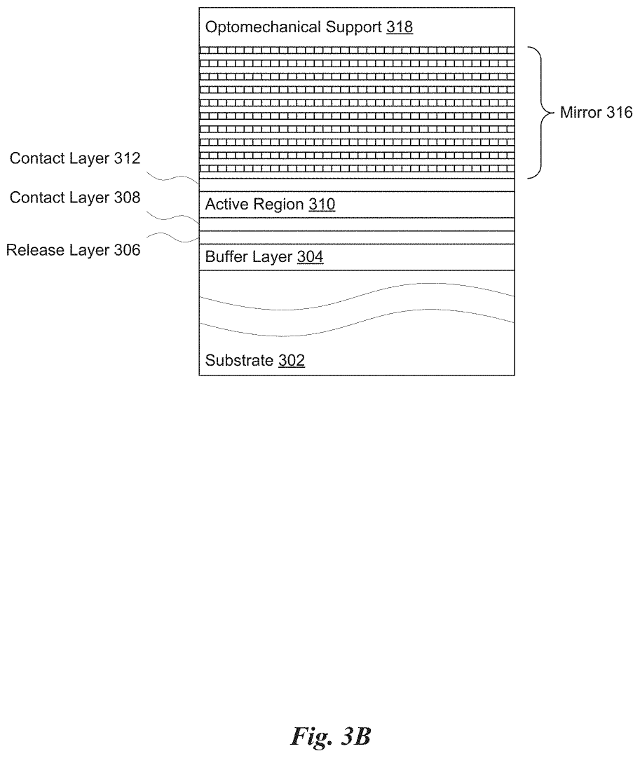

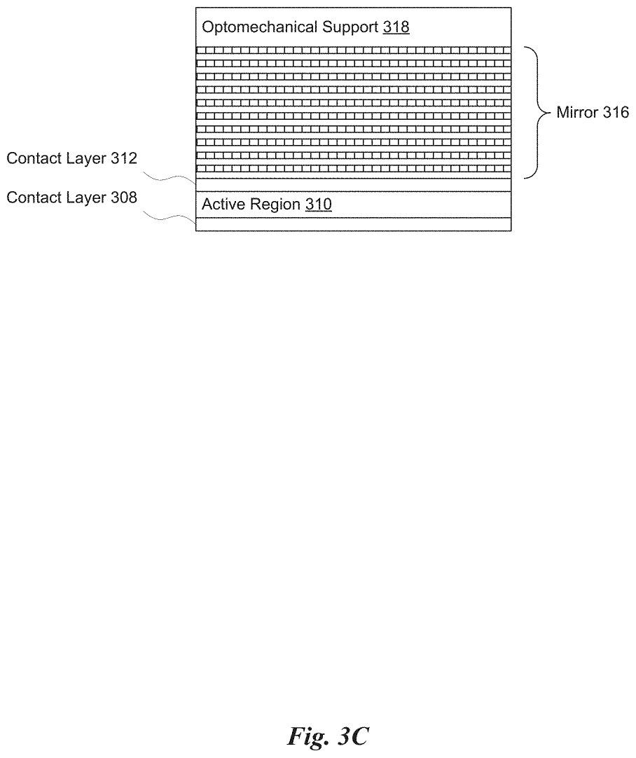

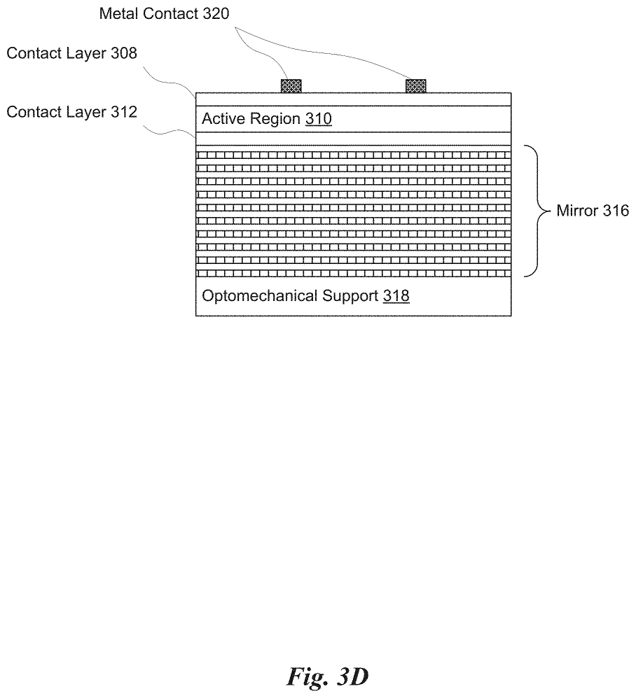

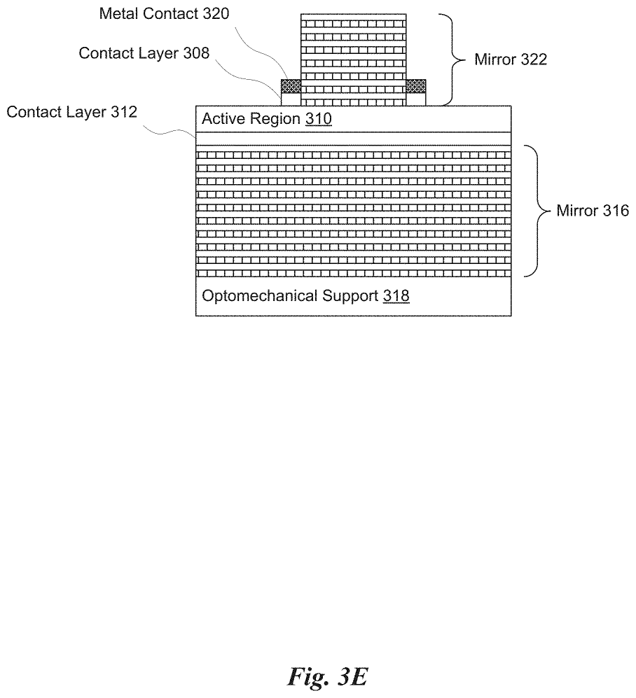

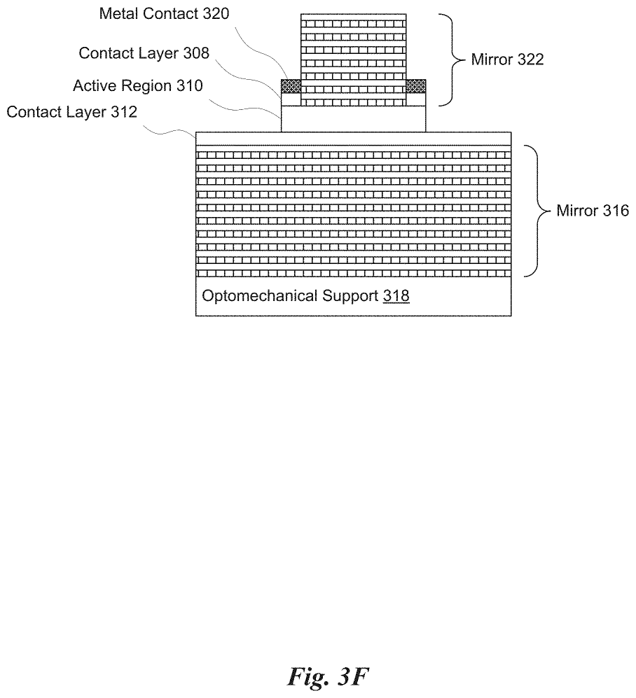

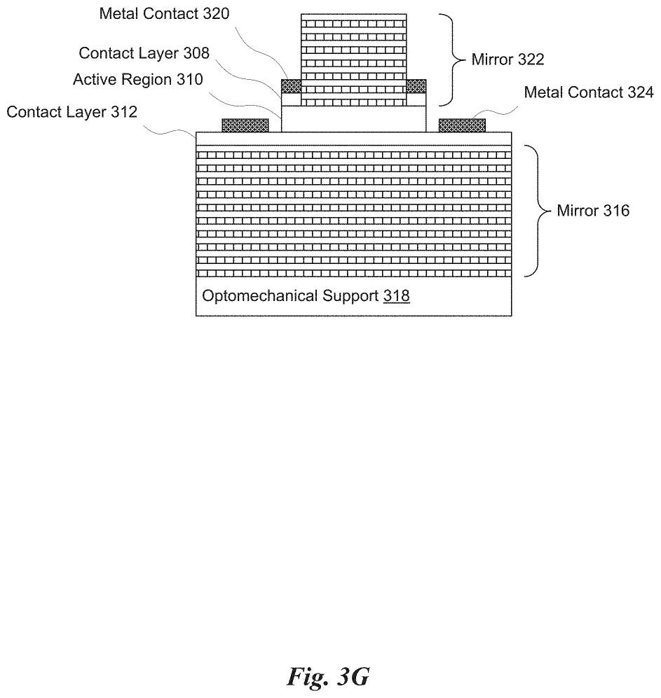

FIGS. 3A-3G show a cross-section of the VCSEL at different stages in production, in accordance with some embodiments. As depicted in FIG. 3A, the epitaxial layers 300 are formed on the substrate 302. The substrate 302 is a semiconductor material, typically in wafer form between 2 and 6 inches in diameter. The optional buffer layer 304 is applied to nucleate the growth on the substrate 302, and may be formed of the same material as the substrate 302, or a different material.

An optional release layer 306 is formed on top of the optional buffer layer 304. In an embodiment, the release layer 306 can include, but is not limited to, the materials of AlAs, AlInAs, AlInP, AlSb, AlAsSb, AlInAsSb, or combinations or alloys thereof. These materials can be selectively dissolved by a HF acid solution, thereby enabling separation of the remainder of the epitaxial layers. In other embodiments, the release layer 306 can include other materials suitable for laser lift-off (LLO), sonic/acoustic techniques, or other methods of separating the substrate 302 from the other epitaxial layers 300.

A front contact layer 308 is formed on top of the release layer 306. In an embodiment, the front contact layer 308 is an n-type contact layer formed from, e.g., InGaAs. It will be appreciated that InGaAs is not as easily etched by HF acid as the release layer 306 and, therefore, the ELO process separates the front contact layer 308 from the substrate 302/buffer layer 304 by etching away the release layer 306.

An active region 310 is formed on top of the front contact layer 308. The active region 310 may include multiple quantum wells formed by thin layers of alternating semiconductor material. In another embodiment, the active region 310 includes only a single quantum well. The quantum well(s) in the active region 310 are the structures that generate the photons at the given wavelength of the laser diode. The active region 310 may include one or more p-n junctions. The active region 310 may include heterobarriers or window layers to passivate one or more other layers inside the active region 310.

A back contact layer 312 is then formed on top of the active region 310. In an embodiment, the back contact layer 312 is a p-type contact layer formed from, e.g., InGaAs, AlInGaAs, GaAsSb, or InGaAsP, doped with Zn. In some embodiments, the back contact layer 312 is an n-type contact layer formed from, e.g., InGaAs, similar to the front contact layer 308. Such embodiments require a separate p-n junction (e.g., a tunnel junction) to be deposited between the back contact layer 312 and the front contact layer 308. In yet other embodiments, the front contact layer 308 is a p-type contact layer and the back contact layer 312 is an n-type contact layer. It will be appreciated that n-type or p-type contact layers refer to semiconductor materials that have n-type or p-type doping. Furthermore, as used herein, front and back are used to describe an order of the contact layers in the stack of layers relative to a “front” side of the device. In some embodiments, both the front contact layer 308 and the back contact layer 312 will be exposed on the same side of the device such that the metal contacts are both disposed on the “front” or “back” of the device. In addition, the meaning of front and back can be arbitrarily assigned to opposite sides of the device.

In some examples, multiple growth techniques may be used in combination or in series to form epitaxial layers. For example, release layer 306 may be grown by MBE with subsequent layers (e.g., front contact layer 308, active region 310, back contact layer 312) being grown by MOCVD. In another example, a metamorphic grading layer may be grown by HYPE with subsequent layers by MOCVD. Other combinations or series of two or more different epitaxial growth techniques may be used.

Although not shown explicitly, the epitaxial layers 300 can include additional layers such as cladding layers (e.g., InP). In addition, the epitaxial layers 300 are typically formed as a series of deposition steps without separate removal (e.g., etching) steps between the formation of each epitaxial layer. In other words, the epitaxial layers form a laminated set of layers that is substantially uniform across the surface of the substrate 302.

As depicted in FIG. 3B, the first mirror 316 is then formed on a top surface of the back contact layer 312. In an embodiment, the first mirror 316 could be formed after selectively etching away areas of the back contact layer 312 (i.e., deposited on the active region 310 rather than the back contact layer 312). This might be implemented to reduce parasitic absorption in the back contact layer 312. In an embodiment, the first mirror 316 is formed from alternating layers of ELO-compatible dielectric materials. As discussed above, in an embodiment, the alternating layers of materials can be formed by Al₂S₃/Al₂Se₃/Ta₂O₅ paired with MgF₂/SiO₂. In other embodiments, the alternating layers of materials can be formed by the following list of materials, which may or may not be ELO-compatible but may be appropriate for alternative methods of achieving separation of the epitaxial layers 300 and the substrate 302, the materials including: aluminum fluoride (AlF₃), silicon nitride (Si₃N₄), titania (TiO₂), zirconia (ZrO₂), zinc sulfide (ZnS), zinc selenide (ZnSe), zinc telluride (ZnTe), antimony triselenide (Sb₂Se₃), gallium phosphide (GaP), amorphous silicon (a-Si), gallium telluride (GaTe), germanium (Ge), antimony sulfide (Sb₂S₃), aluminum nitride (AlN), aluminum oxide (Al₂O₃), silicon oxynitride (SiOₓN_{y}), tantalum pentoxide (Ta₂O₅), thorium tetrafluoride (ThF₄), cerium trifluoride (CeF₃), lead difluoride (PbF₂), lithium fluoride (LiF), barium fluoride (BaF₂), calcium fluoride (CaF₂), yttrium fluoride (YF₃), silica (SiO₂), SU-8 (e.g., bisphenol A novolac epoxy), PermiNex® (a mixture of epoxy resin, cyclopentanone, and [3-(2,3-epoxypropoxy)propyl]trimethoxysilane), and other polyolefins, polycarbonates, polyesters, epoxies, fluoropolymers, derivatives or combinations thereof.

An optional optomechanical support layer 318 is then formed on the top of the first mirror 316. The optomechanical support layer 318 provides stiffness to the film released from the substrate 302. In an embodiment, the optomechanical support layer 318 is formed from a metal such as, e.g., nickel, molybdenum, copper, silver, gold, or alloys or combinations thereof.

It will be appreciated that the production of the VCSEL to this point is similar to conventional VCSELs formed on the substrate with the exception, for the most part, that the layers have been formed in reverse order. This is due to the fact that the conventional VCSELs are not separated from the substrate and, therefore, a first mirror must be formed epitaxially prior to the active epitaxial layers. In addition, because the mirror is formed prior to the active epitaxial layers, the choice of materials that is compatible (i.e., lattice matched or nearly lattice matched) with the substrate is limited in the conventional VCSEL. In other words, choosing a material that is not closely matched with the lattice constant of the substrate material could make it difficult or impossible to grow the active region on top of the mirror. By forming the active region on the substrate prior to depositing the mirror, a broader array of materials can be used.

As depicted in FIG. 3C, the epitaxial layers 300 are separated from the substrate 302. In an embodiment, the release layer 306 is etched away using an HF acid solution, leaving the front contact layer 308 exposed on a bottom surface of the released film. The substrate 302 can be processed to remove the buffer layer 304 such that the substrate 302 can be used in subsequent production runs. Being able to reuse the substrate 302 can reduce the cost and environmental footprint of VCSEL manufacturing.

After separation from the substrate 302, the released film is inverted such that the optomechanical support layer 318 is positioned on the bottom of the film and the front contact layer 308 is positioned on the top of the film. As depicted in FIG. 3D, a metal contact 320 is deposited onto the front (i.e., now top) contact layer 308. In an embodiment, a layer of photoresist is coated on top of the wafer and exposed via a pattern. The photoresist is then selectively removed to leave a pattern with openings that expose portions of the exposed front contact layer. A metal layer is deposited on the patterned wafer via physical deposition (e.g., evaporation, sputtering, etc.), chemical vapor deposition (CVD), plating such as electroplating, or the like. The photoresist is then removed, and in the process, also removing metal that was deposited on top of the photoresist while leaving intact metal that was deposited on the semiconductor layer. In an embodiment, the metal contact 320 forms an annular structure on a surface of the front contact layer 308. It will be appreciated that any other well-known technique for depositing the metallic pattern of the metal contact 320 onto the front contact layer 308 is within the scope of the present disclosure.

The front contact layer 308 material that is not directly below the metal contact 320 may then be removed by a self-aligned process using the metal contact 320 as the masking material, or by another photolithographic process.

As depicted in FIG. 3E, a second mirror 322 is formed on top of the active region 310. In an embodiment, the second mirror 322 is formed within the annular metal contact 320. The layers can be formed by deposition followed by photolithography and etching, or by a lift-off process like the one described above for the metallization of the front contact layer 308. In some embodiments, the second mirror 322 is formed of the same materials as the first mirror 316, and may or may not contain the same number of alternating layers. In other embodiments, the second mirror 322 is formed of different materials compared to the materials of the first mirror 316, and may or may not contain the same number of alternating layers.

As depicted in FIG. 3F, a mesa is formed by removing a portion of the active region 310. The mesa helps confine the photons produced in the active region 310 to the center of the VCSEL. Removing the portion of the active region 310 also serves to expose the back contact layer 312, thereby allowing a second metal contact to be formed thereon and accessed from the same side of the device as the metal contact 320.

As depicted in FIG. 3G, a metal contact 324 is deposited onto the back contact layer 312. In an embodiment, the metallization proceeds by a photolithographic patterning process, followed by a metal layer deposition on the back contact layer 312 via physical deposition (e.g., evaporation, sputtering, etc.), chemical vapor deposition (CVD), plating such as electroplating, or the like, followed by removal of the photoresist and the metal above the photoresist in a lithographic metal lift-off process. In an embodiment, the metal contact 324 forms an annular ring on a surface of the back contact layer 312 that surrounds the metal contact 320, mesa, and second mirror 322. It will be appreciated that any other well-known technique for depositing the metallic pattern of the metal contact 324 onto the back contact layer 312 is within the scope of the present disclosure.

Following the stage shown in FIG. 3G, the VCSELs may be separated via dicing or slicing the film to form individual VCSELs or VCSEL arrays. The VCSELs can be packaged in a laser diode body and combined with optional optical components such as a lens or microlens array.

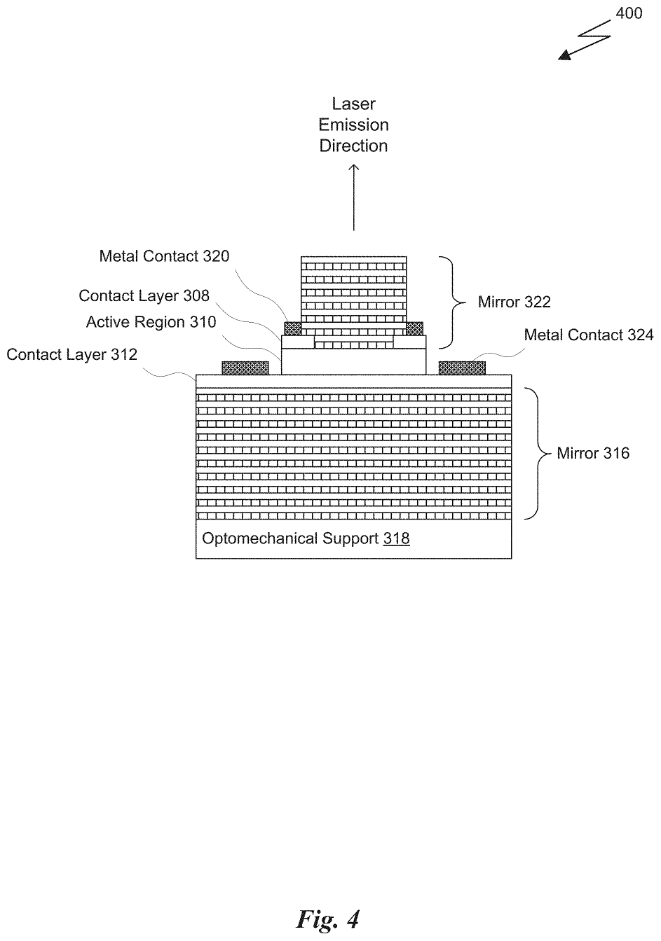

FIG. 4 illustrates a VCSEL 400, in accordance with a first embodiment. As depicted in FIG. 4, the structure of the VCSEL 400 is similar to that described above in connection with the method 200 and/or the stages of FIGS. 3A-3G. More specifically, the VCSEL 400 includes an optomechanical support layer 318, a first mirror 316, a back contact layer (p-type contact layer) 312, a metal contact 324, an active region 310, a front contact layer (n-type contact layer) 308, metal contact 320 and a second mirror 322. In some embodiments, the front contact layer 308 can encroach into one or more pairs of layers of the second mirror 322 simply by changing the size of the apertures used in the patterns from the front contact layer 308 and the second mirror 322.

The direction of the emitted laser beam is through the second mirror 322. Although not shown explicitly in FIG. 4, in some embodiments, the active region 310 can include an aperture formed by proton implantation in the outer portion of the mesa in order to constrain current and optical transmission to the center of the VCSEL 400.

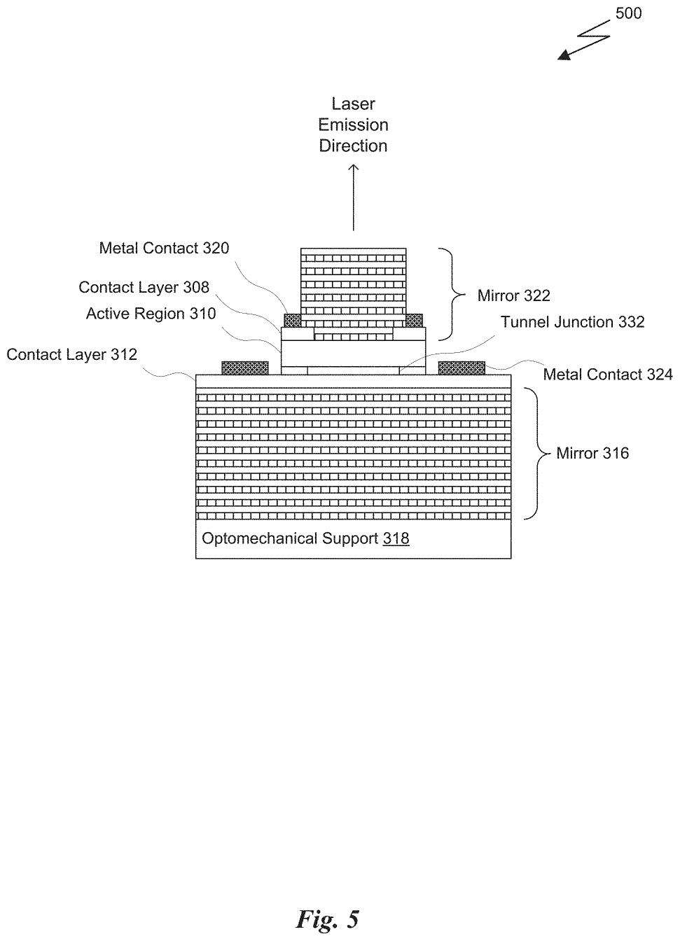

FIG. 5 illustrates a VCSEL 500, in accordance with a second embodiment. The VCSEL 500 is similar to the VCSEL 400 except the VCSEL 500 includes a buried tunnel junction 332 (e.g., a p-n junction) disposed between the active region 310 and the back contact layer 312. In such embodiments, the back contact layer 312 can also be an n-type contact layer, similar to the front contact layer 308.

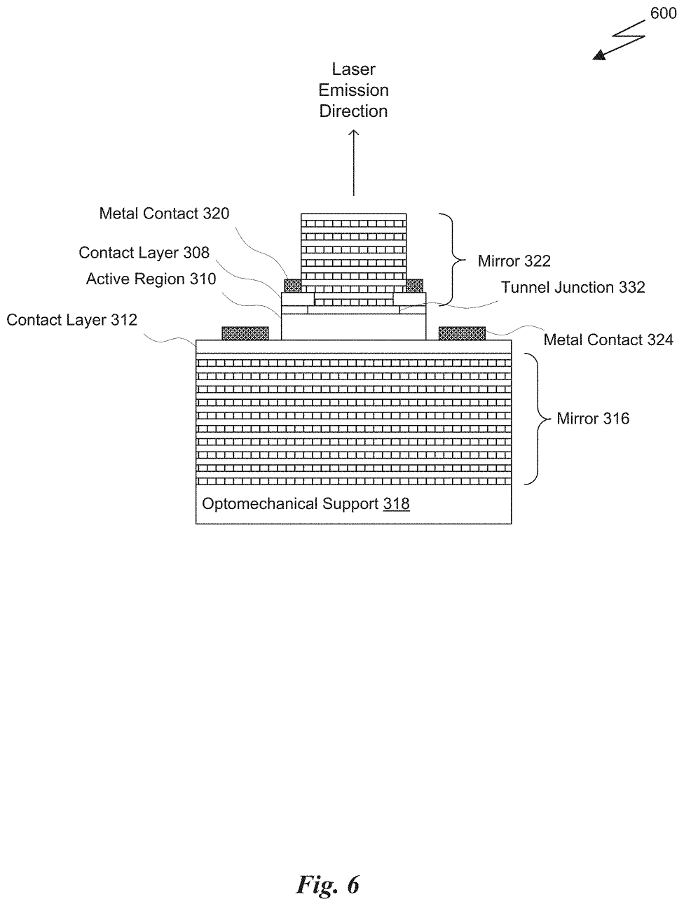

FIG. 6 illustrates a VCSEL 600, in accordance with a third embodiment. The VCSEL 600 is similar to the VCSEL 500 except the VCSEL 600 disposes the buried tunnel junction 332 between the active region 310 and the front contact layer 308.

FIG. 7 illustrates a VCSEL 700, in accordance with a fourth embodiment. The VCSEL 700 is similar to the VCSEL 400 except the VCSEL 700 replaces the single optomechanical support layer 318 with a plurality of layers including an metal adhesion layer 342 adjacent to the first mirror 316, a metal mirror 344 adjacent to the metal adhesion layer 342 opposite the first mirror 316, and a support layer 346 adjacent to the metal mirror 344 opposite the metal adhesion layer 342. In an embodiment, the metal adhesion layer 342 is formed of a nickel or chromium material. The metal mirror 344 is formed from, e.g., a gold, silver, aluminum, or copper material. The support layer 346 is formed from, e.g., a nickel, molybdenum, or copper material. In some embodiments, the metal adhesion layer 342 is optional and can be omitted. The metal mirror 344 reflects light passing through the first mirror 316 to be reflected back towards the front surface of the VCSEL 700, allowing for improved reflector quality compared to an embodiment that does not include a metal mirror on the backside of the dielectric reflector. This could enable a design with fewer layers in the mirror.

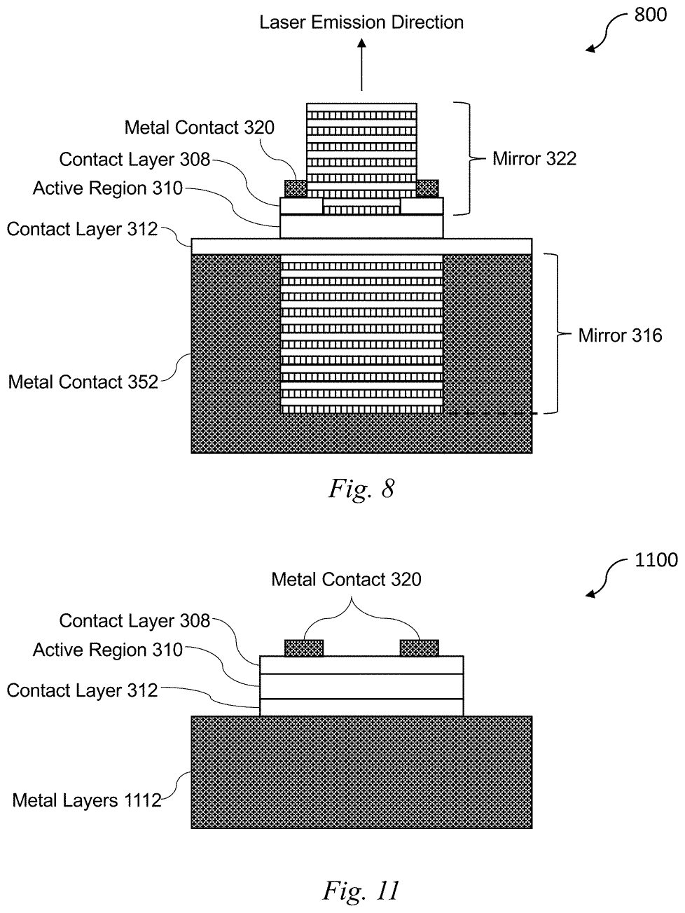

FIG. 8 illustrates a VCSEL 800, in accordance with a fifth embodiment. The VCSEL 800 is similar to the VCSEL 400 except the VCSEL 800 forms the metal contact 352 on a bottom surface of the back contact layer 312. The metal contact 352 is a metal material and doubles as a reflective coating as a bottom mirror for the first mirror 316 as well as a support structure that replaces the need for the optomechanical support layer 318. Furthermore, the metal contact 352 can be deposited prior to the separation of the epitaxial layers 300 from the substrate by etching (or through a liftoff technique, as described above) the first mirror 316 to expose the back contact layer 312 and then depositing the metal film on the exposed back contact layer 312 as well as the surface of the first mirror 316. Alternatively, the metal contact 352 can be deposited after the separation of the epitaxial layers 300 from the substrate 302, but prior to inverting the film to form the second mirror 322 on the top surface of the film.

FIG. 9 illustrates a VCSEL 900, in accordance with a sixth embodiment. The VCSEL 900 is similar to the VCSEL 400 except the VCSEL 900 includes a transparent or semi-transparent optomechanical support layer 362 in place of the opaque optomechanical support layer 318. In this embodiment, the direction of the laser emission can be through the bottom of the VCSEL 900 through the optomechanical support layer 362. Although not shown explicitly in FIG. 9, in some embodiments, the top surface of the second mirror 322 can include an additional mirror layer (e.g., gold, silver, copper, aluminum, etc.) that reflects light back towards the first mirror 316 to be emitted from the bottom surface of the VCSEL 900.

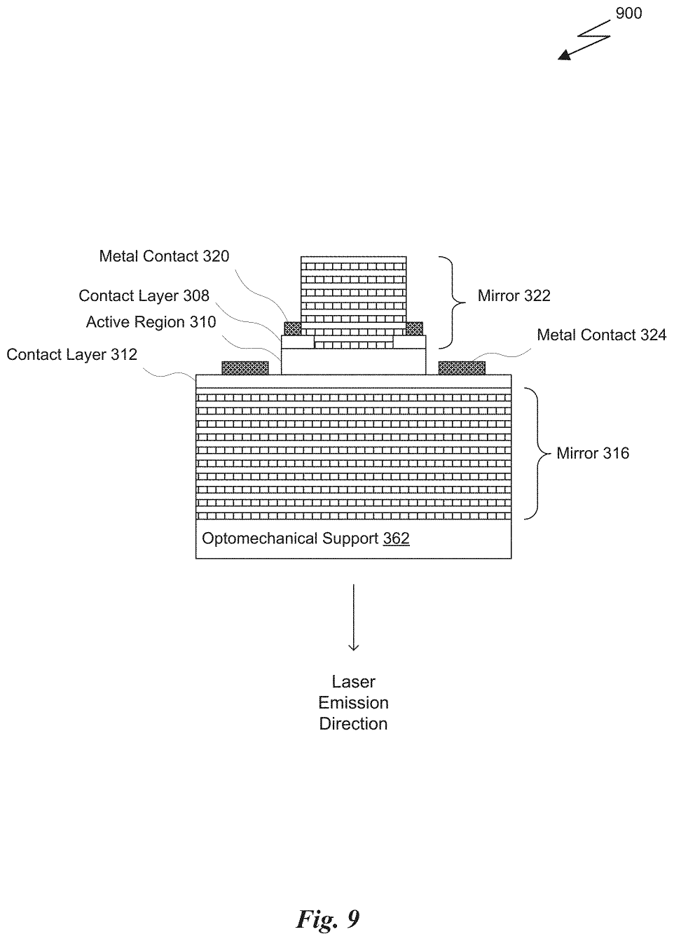

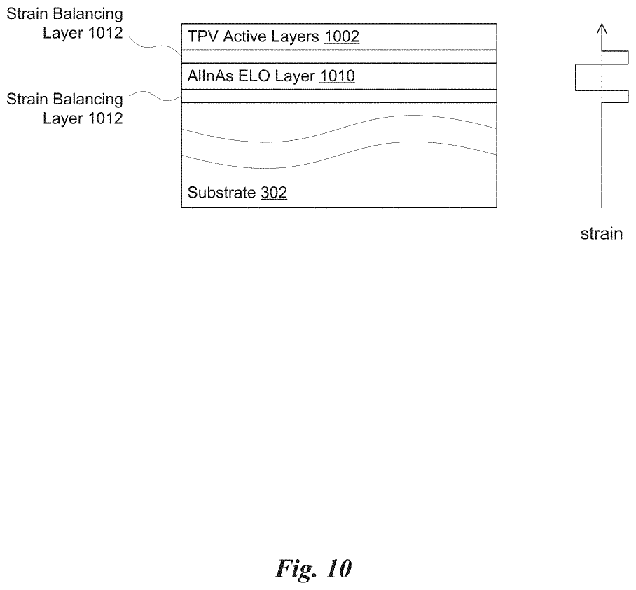

FIG. 10 illustrates a multi-layered, strain-balanced release layer, in accordance with some embodiments. It will be appreciated that a release layer 306 formed of AlₓIn₁₋ₓAs, where x>˜0.48, may be in tensile strain due to a possible mis-match between lattice parameters of AlInAs and the substrate material. Forming the release layer 306 from a single layer of AlInAs, therefore, may create stress in the epitaxial layers formed on top of the release layer 306. One way to alleviate this stress in the subsequent epitaxial layers is to form a multi-layered release layer by sandwiching an ELO release layer 1010 (e.g., AlₓIn₁₋ₓAs, where x>˜0.48) between two or more strain-balancing layers 1012 formed from a strain-balancing material such as InAsP or InGaAs, or AlₓIn₁₋ₓAs where x<˜0.48. The mis-match of the lattice parameters between the strain-balancing material and the substrate material places the strain-balancing material in compressive strain, which balances out the tensile strain in the ELO release layer 1010. Consequently, the stress is reduced in the subsequent epitaxial layers.

In other embodiments, there are multiple repetitions of the 1012/1010 layer sequence. In yet other embodiments, strain balancing can be achieved by the formation of a single strain-balancing layer 1012, deposited either before or after the release layer 1010.

In various embodiments, the release layer 1010 can be formed from materials such as AlAs, AlP, AlInAs, AlInP, AlAsSb, AlInAsSb, AlInPSb, AlInAsP, or alloys thereof, which are in tensile strain with the substrate material as well as the materials selected for the strain-balancing layers 1012. The strain-balancing layers 1012 can be formed from materials such as InAs, InAsP, AlInAs, InGaAs, GaSb, GaAsSb, AlSb, AlAsSb, InGaAsSb, InAsSb, or alloys thereof, which are in compressive strain with the substrate material as well as the material selected for the release layer 1010. In other embodiments, the release layer 1010 can be formed from materials such as AlSb, AlInAs, AlAs Sb, AlInAsSb, AlInPSb, or alloys thereof, which are in compressive strain with the substrate material as well as the materials selected for the strain-balancing layers 1012; while the strain-balancing layers 1012 can be formed from materials such as AlInAs, GaAs, InGaAs, GaAsSb, InGaAsSb, InGaAsSb, or alloys thereof, which are in tensile strain with the substrate material as well as the material selected for the release layer 1010.

FIG. 11 illustrates an optoelectronic device, in accordance with a seventh embodiment. Optoelectronic device 1100 includes metal contact 320, contact layer 308, active region 310 and contact layer 312, as described herein. In this embodiment, optoelectronic device 1100 also includes metal layers 1112, which may comprise one, some, or all, of an adhesion metal (e.g., metal adhesion layer 342 in FIG. 7), a reflective metal (e.g., metal layer 128 in FIG. 1B, metal mirror 344 in FIG. 7) and a supportive metal (e.g., metal layer 128 in FIG. 1B, support layer 346 in FIG. 7). In some examples, metal layers 1112 may be deposited using one, or a combination, of common metallization techniques such as plating, evaporation, sputtering, chemical vapor deposition, and the like. In some examples, metal layers 1112 and/or metal contact 320 also may serve as a conductive layer to conduct current out of optoelectronic device 1100. All like-numbered elements in FIG. 11 are the same or similar to their corresponding elements in previous figures (e.g., FIGS. 3A-9).

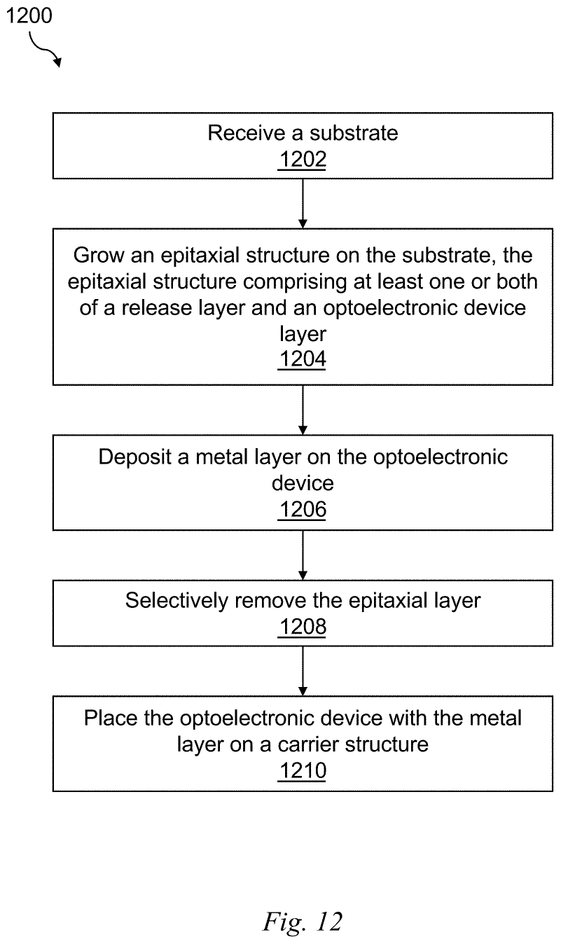

FIG. 12 illustrates a flowchart of a method for manufacturing an optoelectronic device, in accordance with some embodiments. As those skilled in the art will understand, any process that results in deposition or removal of the structures described herein is within the scope of the present disclosure, and that the steps described in method 1200 may be performed in different order. Method 1200 begins with receiving a substrate at step 1202. An epitaxial structure may be grown or deposited on the substrate at step 1204, the epitaxial structure comprising at least one or both of a release layer and an optoelectronic device layer. In some examples, the substrate may comprise a semiconductor material (e.g., InP) having a lattice constant between 5.7 and 6.0 Angstroms. As described herein, the epitaxial layer may comprise a single layer or a multi-layer stack. The epitaxial structure may include a buffer layer, a release layer, and optoelectronic device layers. A metal layer (e.g., metal layer 128 in FIG. 1B, any of the metal layers and support layers described in FIGS. 3A-9) may be deposited on the optoelectronic device at step 1206. Step 1206 may also include the deposition of a dielectric material or materials, usually prior to depositing metals. The epitaxial layer may be selectively removed, for example by ELO techniques described herein, at step 1208. For example, the optoelectronic device layer with the metal layer, epitaxial layer and substrate may be exposed to (e.g., submerged in) a hydrofluoric acid solution, as described herein, the optoelectronic device and the metal layer being resistant to (i.e., maintaining its structural and compositional integrity in) the hydrofluoric acid solution. The optoelectronic device, optionally with the metal layer, may be placed on a carrier structure (e.g., a wafer) at step 1210. In some examples, the resulting optoelectronic device comprises a thin film, single crystal device.

As those skilled in the art will understand, a number of variations may be made in the disclosed embodiments, all without departing from the scope of the invention, which is defined by the appended claims. It should be noted that although the features and elements are described in particular combinations, each feature or element can be used alone without other features and elements or in various combinations with or without other features and elements.

To facilitate an understanding of the subject matter described herein, many aspects are described in terms of sequences of actions. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

What is claimed is:

1. A method for forming an optoelectronic device on a substrate, comprising:
growing an epitaxial structure on the substrate, wherein the substrate comprises a semiconductor material having a lattice constant between 5.7 and 6.0 Angstroms, and wherein the epitaxial structure includes an epitaxial device layer;
depositing a metal layer on the epitaxial structure; and
selectively removing the epitaxial structure and metal layer from the substrate, thereby separating the optoelectronic device from the substrate.

2. The method of claim 1, wherein the epitaxial structure further comprises a release layer with a high aluminum content.

3. The method of claim 2, wherein selectively removing the epitaxial structure and metal layer from the substrate occurs by epitaxial lift off (ELO).

4. The method of claim 3, wherein the epitaxial lift off (ELO) comprises exposing the epitaxial structure to a hydrofluoric acid (HF) solution.

5. The method of claim 4, wherein the epitaxial device layer is resistant to the HF solution.

6. The method of claim 4, wherein the metal layer is resistant to the HF solution.

7. The method of claim 1, wherein the optoelectronic device comprises a thermophotovoltaic (TPV) device.

8. The method of claim 1, wherein the optoelectronic device comprises a vertical cavity surface emitting laser (VCSEL) device.

9. The method of claim 1, wherein the metal layer comprises a reflective metal.

10. The method of claim 7, wherein the reflective metal is formed from one, or a combination, of gold, silver, aluminum, or copper.

11. The method of claim 1, wherein the metal layer comprises a supportive metal.

12. The method of claim 9, wherein the supportive metal is formed from one, or a combination, of nickel, molybdenum, or copper.

13. The method of claim 1, wherein the metal layer comprises a dielectric material.

14. The method of claim 13, wherein the dielectric material includes one, or a combination, of arsenic trisulfide, arsenic triselenide, tantalum pentoxide, magnesium fluoride, SU-8, PermiNex®.

15. The method of claim 1, further comprising placing the optoelectronic device with the metal layer on a carrier structure.

16. The method of claim 1, wherein the substrate comprises Indium Phosphide.

17. The method of claim 1, further comprising post-processing the substrate for reuse.

18. The method of claim 1, wherein growing the epitaxial layer includes using one, or a combination, of metal organic chemical vapor deposition (MOCVD), molecular beam epitaxy (MBE), hydride vapor deposition (HYPE), or liquid phase epitaxy (LPE).

19. An optoelectronic device, comprising:
an optoelectronic device structure including an epitaxial device layer having a lattice constant between 5.7 and 6.0 Angstroms;
a metal layer deposited onto a surface of the optoelectronic device structure; and
a carrier structure,
wherein the optoelectronic device comprises a thin film, single crystal device.

20. The optoelectronic device of claim 19, wherein the optoelectronic device structure comprises a thermophotovoltaic (TPV) device.

21. The optoelectronic device of claim 19, wherein the optoelectronic device structure comprises a vertical cavity surface emitting laser (VCSEL) device.

22. The optoelectronic device of claim 19, wherein the metal layer comprises a reflective metal.

23. The optoelectronic device of claim 22, wherein the reflective metal is formed from one, or a combination, of gold, silver, aluminum, or copper.

24. The optoelectronic device of claim 19, wherein the metal layer comprises a supportive metal.

25. The optoelectronic device of claim 24, wherein the supportive metal is formed from one, or a combination, of nickel, molybdenum, or copper.

26. The optoelectronic device of claim 19, wherein the epitaxial device layer is grown on an epitaxial release layer, which in turn is grown on a substrate by one, or a combination, of metal organic chemical vapor deposition (MOCVD), molecular beam epitaxy (MBE), hydride vapor deposition (HYPE), or liquid phase epitaxy (LPE).

27. The optoelectronic device of claim 26, wherein the substrate comprises Indium Phosphide.
